(19) United States
(12) Patent Application Publication
(10) Pub. No.: US 2024/0332297 A1
(43) Pub. Date: Oct. 3, 2024

(54) REPLACEMENT SOURCE/DRAIN CONTACT METHOD IN COMPLEMENTARY FIELD EFFECT TRANSISTOR (CFET) DEVICES

(71) Applicant: Applied Materials, Inc., Santa Clara, CA (US)

(72) Inventors: Ashish PAL, San Ramon, CA (US); El Mehdi BAZIZI, San Anselmo, CA (US); Balasubramanian PRANATHARTHIHARAN, Santa Clara, CA (US)

(21) Appl. No.: 18/595,286

(22) Filed: Mar. 4, 2024

Related U.S. Application Data
(60) Provisional application No. 63/456,435, filed on Mar. 31, 2023.

(51) Int. Cl. H01L 27/092; H01L 29/06; H01L 29/08; H01L 29/417; H01L 29/66

(52) U.S. Cl. CPC H01L 27/092; H01L 29/0673; H01L 29/0847; H01L 29/41725; H01L 29/66545

(57) ABSTRACT

A semiconductor structure forming a complementary field-effect transistor (CFET) includes a metal gate, a bottom field effect transistor (FET) module, the bottom FET module including a plurality of channel layers extending through the metal gate in a first direction, and a bottom source/drain (S/D) contact electrically connected to the plurality of channel layers via a bottom epitaxial (epi) S/D and a bottom interface, and a top FET module stacked on the bottom FET module in a second direction that is orthogonal to the first direction, the top FET module including a plurality of channel layers extending through the metal gate in the first direction, and a top source/drain (S/D) contact electrically connected to the plurality of channel layers via a top epitaxial (epi) S/D and a top interface, wherein the bottom S/D contact and the top S/D contact each comprise cobalt (Co) or tungsten (W).

### CROSS-REFERENCE TO RELATED APPLICATIONS

This application claims priority to U.S. Provisional Application Ser. No. 63/456,435 filed Mar. 31, 2023, which is herein incorporated by reference in its entirety.

### BACKGROUND

### Field

Embodiments described herein generally relate to semiconductor device fabrication, and more particularly, to methods for forming complementary field effect transistor (CFET) devices.

### Description of the Related Art

To continue scaling beyond the physical limit of planar metal oxide semiconductor field effect transistor (MOSFET), three-dimensional FinFET, stacked nanosheet gate-all-around FET (GAA FETs), and complementary FET (CFET) have been proposed. In a CFET architecture, n- and p-devices are stacked on top of each other vertically, eliminating the n-p spacing from the standard cell height. In the currently proposed process flows, a contact trench in the bottom device is filled with silicide and metal contact plug prior to the formation of the top device. As a result, the silicide and the contact plug formed of currently known materials, such as titanium silicide, cobalt, or tungsten, may not withstand high temperature processes to form the top device and degrade during the high temperature processes. The use of material that may withstand such high temperature processes may cause high resistance and lead to complexity in deposition and etch processes.

Therefore, there is a need for improved methods to fabricate silicide and metal contact plug in a bottom device of a CFET architecture.

### SUMMARY

Embodiments of the present disclosure provide a semiconductor structure forming a complementary field-effect transistor (CFET). The semiconductor structure includes a metal gate, a bottom field effect transistor (FET) module, the bottom FET module including a plurality of channel layers extending through the metal gate in a first direction, and a bottom source/drain (S/D) contact electrically connected to the plurality of channel layers via a bottom epitaxial (epi) S/D and a bottom interface, and a top FET module stacked on the bottom FET module in a second direction that is orthogonal to the first direction, the top FET module including a plurality of channel layers extending through the metal gate in the first direction, and a top source/drain (S/D) contact electrically connected to the plurality of channel layers via a top epitaxial (epi) S/D and a top interface, wherein the bottom S/D contact and the top S/D contact each comprise cobalt (Co) or tungsten (W).

Embodiments of the present disclosure provide a method of forming a complementary field-effect transistor (CFET). The method includes performing a top cover spacer formation process to deposit a top cover spacer covering exposed surface of a top nanosheet and a spacer around the top nanosheet along a first plane orthogonal to a first direction, wherein the top nanosheet is stacked on a bottom nanosheet in a second direction orthogonal to the first direction, and the top nanosheet and the bottom nanosheet each comprise a plurality of channel layers extending through a dummy gate in the first direction, performing a bottom epitaxial (epi) source/drain (S/D) formation process to form a bottom epi S/D on an exposed surface of the bottom nanosheet along the first plane, performing a bottom contact patterning and sacrificial fill process to deposit a bottom inter-layer dielectric (ILD) on surfaces of a spacer around the bottom epi S/D, pattern the bottom ILD, forming a dummy contact, and remove the top cover spacer, performing a top epi S/D formation process to form a top epi S/D on an exposed surface of the top nanosheet along the first plane and a top ILD around the top epi S/D, performing a replacement metal gate (RMG) process to replace the dummy gate with a metal gate, performing a top contact patterning and metal fill process to pattern the top ILD, forming a top S/D contact, subsequent to the bottom epi S/D formation process, the top epi S/D formation process, and the RMG process, performing a dummy contact strip process to selectively etch the dummy contact, and performing a bottom replacement S/D contact formation process to form a bottom S/D contact in the portion etched in the dummy contact strip process.

Embodiments of the present disclosure provide a semiconductor structure forming a complementary field-effect transistor (CFET). The semiconductor structure includes a metal gate, a bottom field effect transistor (FET) module, the bottom FET module including a plurality of channel layers extending through the metal gate in a first direction, and a dummy contact connected to the plurality of channel layers via a bottom epitaxial (epi) S/D and a bottom interface, and a top FET module stacked on the bottom FET module in a second direction that is orthogonal to the first direction, the top FET module including a plurality of channel layers extending through the metal gate in the first direction, and a top source/drain (S/D) contact electrically connected to the plurality of channel layers via a top epitaxial (epi) S/D and a top interface, wherein the dummy contact comprises the dummy contact comprises silicon oxide (SiO₂), silicon nitride (Si₃N₄), silicon carbide (SiC), or a combination thereof, and the top S/D contact comprises cobalt (Co) or tungsten (W).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2A is an isometric view of a portion of a semiconductor structure that may form a complementary field-effect transistor (CFET), according to one or more embodiments of the present disclosure. FIG. 2B illustrates a cut out of the semiconductor structure of FIG. 2A along the ZX plane including the line 2B-2B shown in FIG. 2A.

FIGS. 3A and 3B depict a process flow diagram of a method of forming cell transistors in a semiconductor structure according to one embodiment.

FIGS. 4A, 4B, 4C, 4D, 4E, 4F, 4G, 4H, 4I, 4J, 4J′, 4K, 4L, 4M, 4N, and 4O are isometric views of a portion of a semiconductor structure corresponding to various states of the method of FIGS. 3A and 3B.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for complementary FET (CFET) devices. In the methods described herein, a dummy contact is deposited in place for a source/drain (S/D) contact for a bottom device of a CFET before a top device of the CFET is formed. The dummy contact is replaced with a S/D contact after the formation of the top device that includes high temperature processes. This replacement S/D contact allows the use of most optimized materials for a S/D contact for the bottom device without any thermal budget constraints.

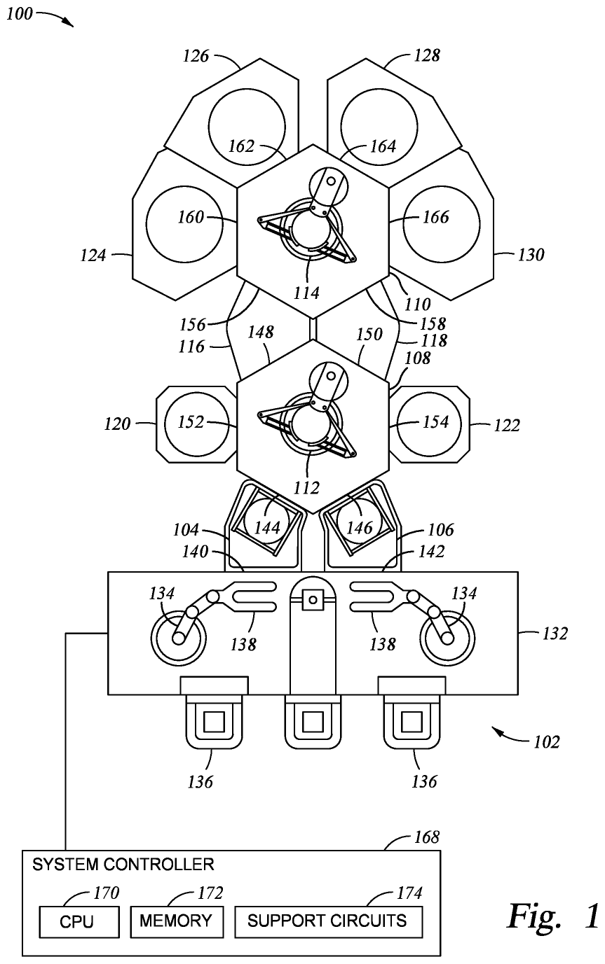

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

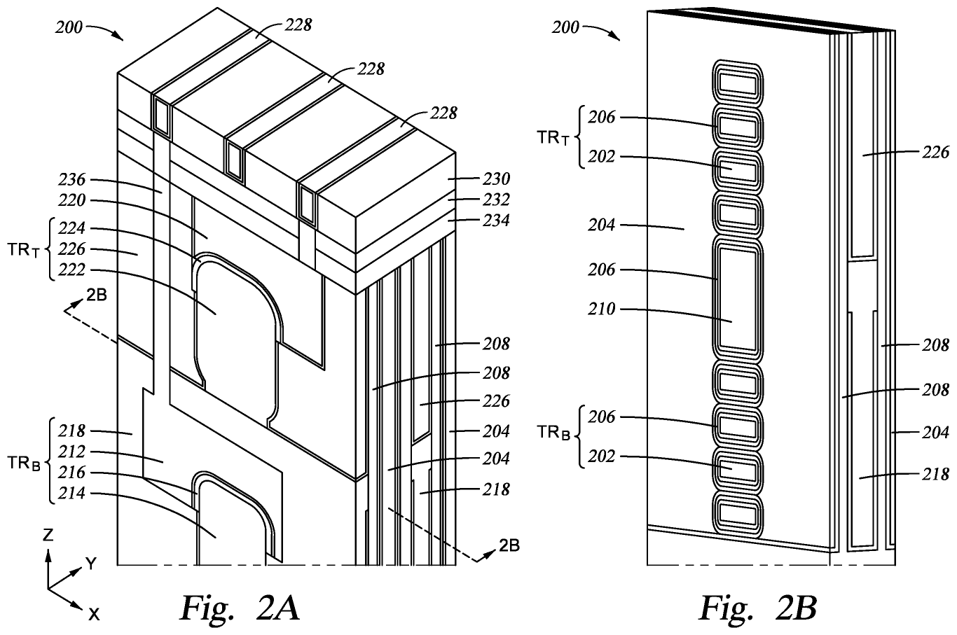

FIG. 2A is an isometric view of a portion of a semiconductor structure 200 that may form a complementary field-effect transistor (CFET), according to one or more embodiments of the present disclosure. FIG. 2B illustrates a cut out of the semiconductor structure 200 along the ZX plane including the line 2B-2B shown in FIG. 2A. The semiconductor structure 200 includes a bottom field effect transistor (FET) module TR_{B}, and a top FET module TR_{T} stacked on the bottom FET module TR_{B} in the Z direction. The bottom FET module TR_{B} and the top FET module TR_{T} each include channel layers 202 extending through a metal gate 204 in the Y direction. The channel layers 202 may be encapsulated in a liner 206. Surfaces of the metal gates 204 along the ZX plane are covered by spacers 208. The channel layers 202 in the bottom FET module TR_{B} are electrically isolated from the channel layers 202 in the top FET module TR_{T} by a middle dielectric isolation (MDI) 210 and are electrically connected to a bottom S/D contact 212 via a bottom epitaxial (epi) S/D 214 and a bottom interface 216 embedded in a bottom inter-layer dielectric (ILD) 218. In some embodiments, the bottom FET module TR_{B} is p-type and the top FET module TR_{T} is n-type, where the bottom epi S/D 214 is p-type doped and a top epi S/D 222 is n-type doped. In some embodiments, the bottom FET module TR_{B} is n-type and the top FET module TR_{T} is p-type, where the bottom epi S/D 214 is n-type doped and the top epi S/D 222 is p-type doped. The channel layers 202 in the top FET module TR_{T} are electrically connected to a top S/D contact 220 via the top epi S/D 222 and a top interface 224 embedded in a top ILD 226. The bottom S/D contact 212, the top S/D contact 220, and the metal gate 204 are connected to metal layers 228 formed within dielectric layers 230, 232, and 234 via contact plugs 236.

The channel layers 202 may be formed of silicon (Si), germanium (Ge), silicon germanium (SiGe), or indium gallium zinc oxide (IGZO). The metal gates 204, the bottom S/D contact 212, the top S/D contact 220, the metal layers 228, and the contact plugs 236 may be formed of cobalt (Co), tungsten (W), ruthenium (Ru), copper (Cu), molybdenum (Mo), titanium (Ti), nickel (Ni), silver (Ag), gold (Au), iridium (Ir), tantalum (Ta), platinum (Pt), conductive oxides or nitrides thereof, or any combination thereof. In the embodiments described herein, the bottom S/D contact 212 is formed by a replacement S/D contact method, in which a dummy contact formed of material that withstands high temperature processes (such as an epitaxial deposition process and a replacement metal gate process) is replaced with metal after the high temperature processes, as described in detail below. Thus, the bottom S/D contact 212 can be made of metal material listed above, which may not withstand such high temperature processes. The spacers 208 and the MDI 210 may be formed of dielectric material, such as silicon oxycarbide (SiOₓC_{y}). The liner 206 may be formed of titanium nitride (TiN), tantalum nitride (TaN), titanium aluminum carbide (TiAlC), or tungsten (W). The bottom epi S/D 214 and the top epi S/D 222 may be formed of epitaxially grown silicon (Si) or silicon germanium (SiGe). The bottom interface 216 and the top interface 224 may be formed of metal silicide, such as titanium silicide (TiSi₂), molybdenum silicide (MoSi₂), cobalt silicide (CoSi₂), nickel silicide (Ni₂Si), tantalum silicide (TaSi₂), or any combination thereof. The dielectric layer 230, 232, and 234 may be formed of silicon oxide (SiO₂), silicon nitride (Si₃N₄), aluminum oxide (Al₂O₃), or any combination thereof that is carbon doped, such as silicon oxycarbide (SiOC), silicon oxycarbonitride (SiOCN), silicon carbon nitride (SiCN). The bottom ILD 218 and the top ILD 226 may be formed of silicon oxide (SiO₂), silicon oxynitride (SiON), aluminum oxide (Al₂O₃), or any combination thereof.

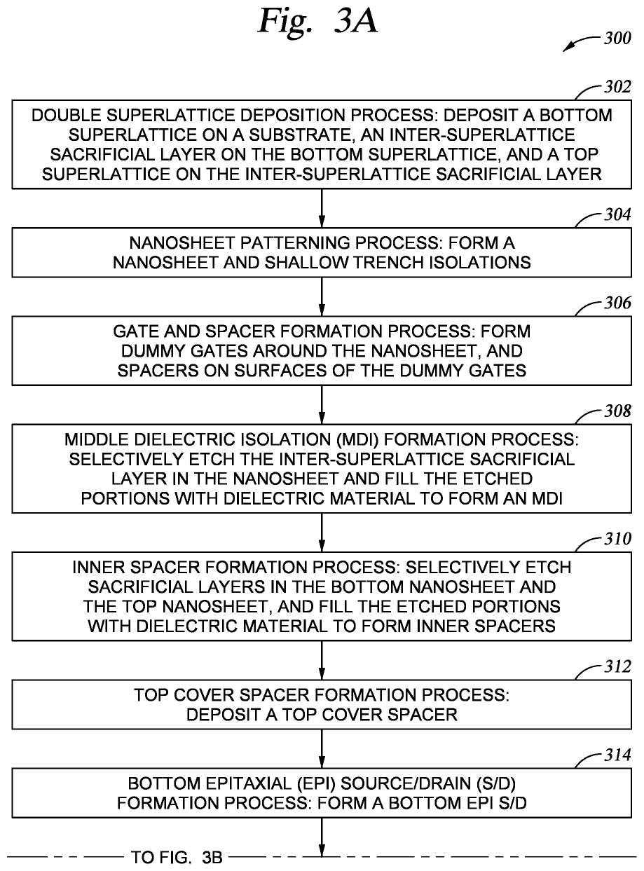

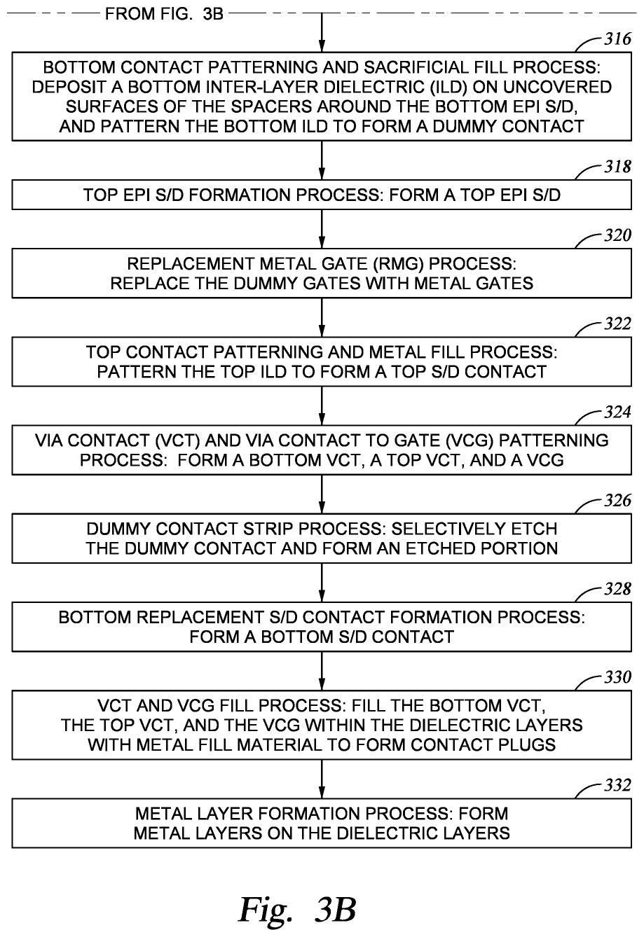

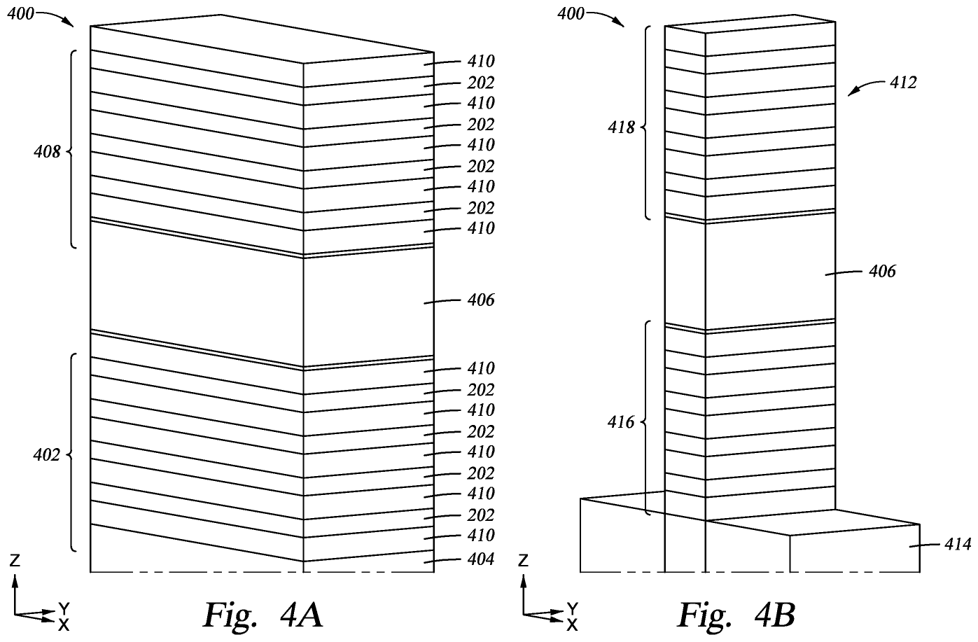

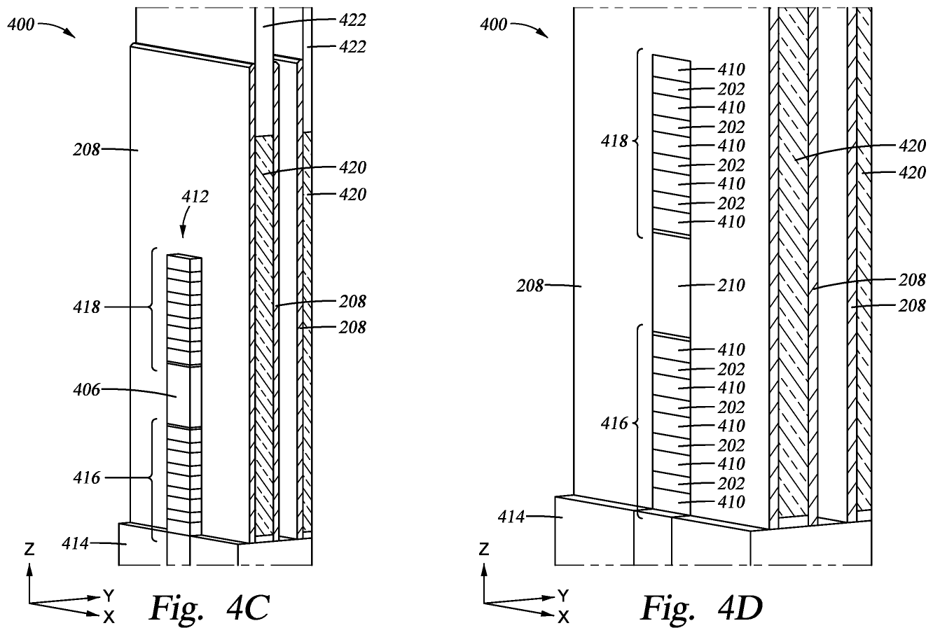

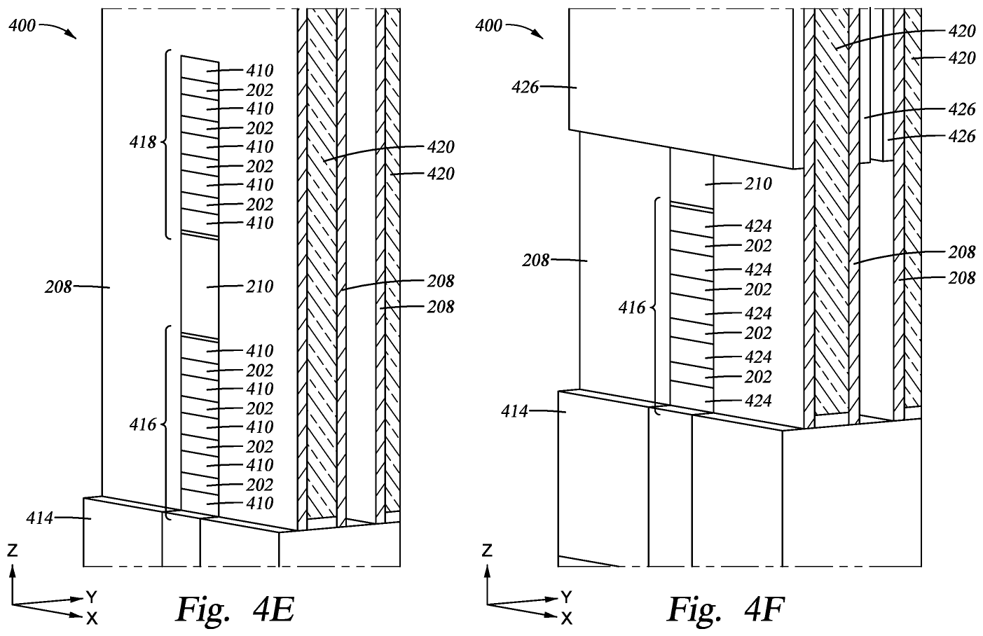

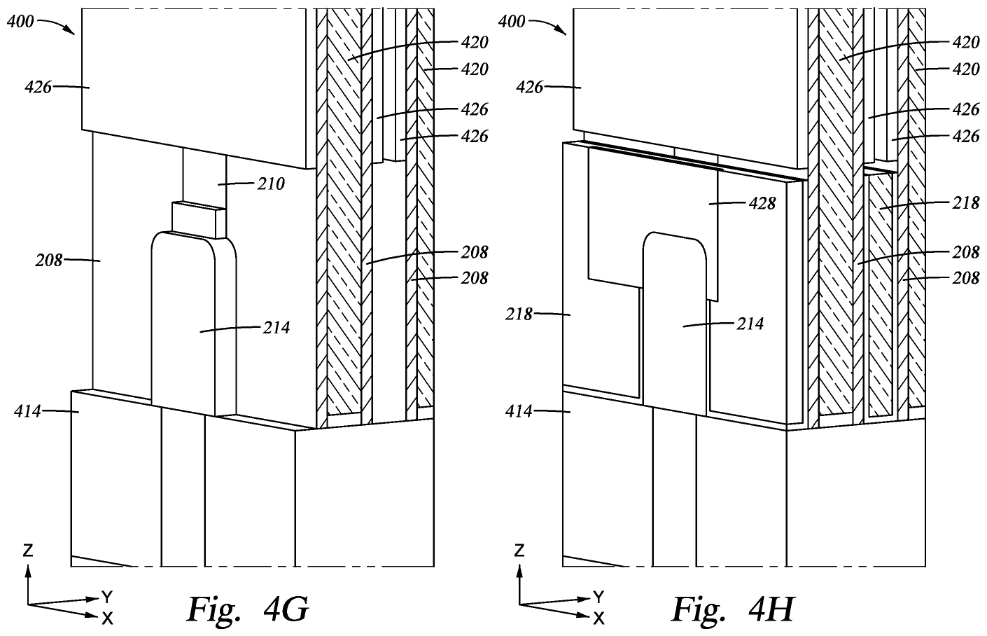

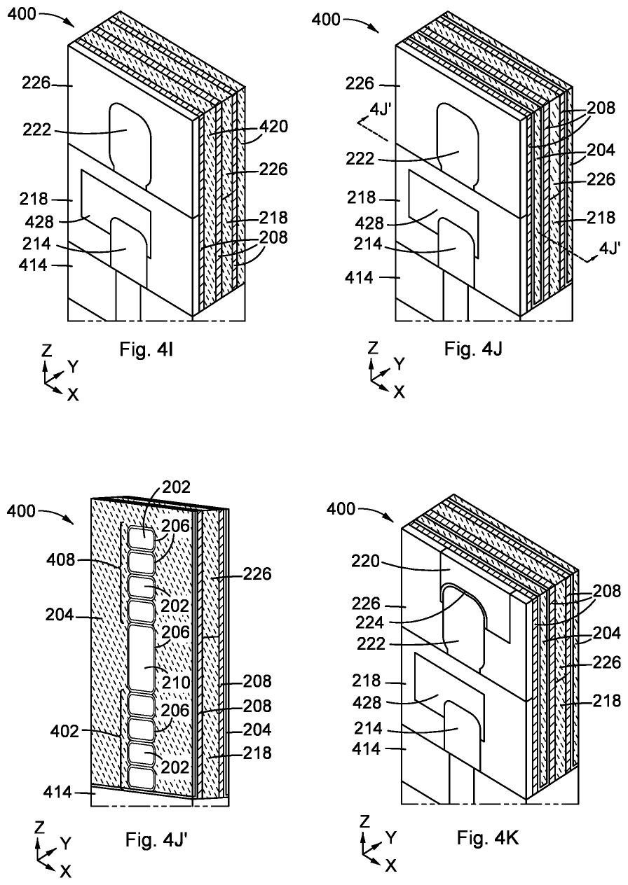

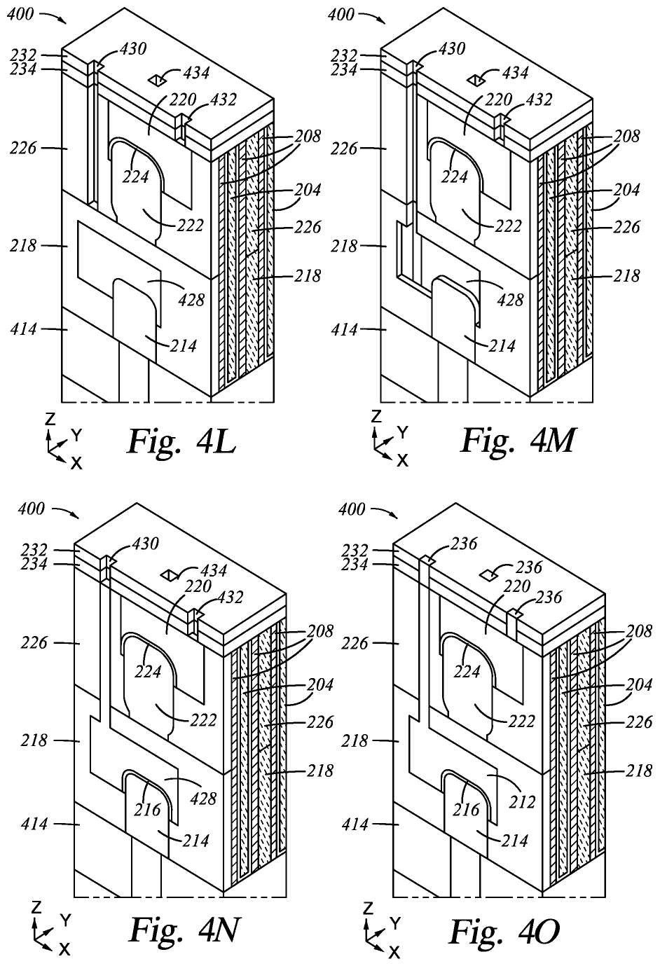

FIGS. 3A and 3B depict a process flow diagram of a method 300 of forming a semiconductor structure 400 that may be the semiconductor structure 200 forming a portion of a complementary field-effect transistor (CFET), according to one or more embodiments of the present disclosure. FIGS. 4A, 4B, 4C, 4D, 4E, 4F, 4G, 4H, 4I, 4J, 4J′, 4K, 4L, 4M, 4N, and 4O are isometric views of a portion of the semiconductor structure 400 corresponding to various states of the method 300. It should be understood that FIGS. 4A, 4B, 4C, 4D, 4E, 4F, 4G, 4H, 4I, 4J, 4J′, 4K, 4L, 4M, 4N, and 4O illustrate only partial schematic views of the semiconductor structure 400, and the semiconductor structure 400 may contain any number of transistor sections and additional materials having aspects as illustrated in the figures. It should also be noted that although the method illustrated in FIGS. 3A and 3B is described sequentially, other process sequences that include one or more operations that have been omitted and/or added, and/or has been rearranged in another desirable order, fall within the scope of the embodiments of the disclosure provided herein.

The method 300 begins with block 302, in which a double superlattice deposition process is performed to deposit a bottom superlattice 402 on a substrate 404, an inter-superlattice sacrificial layer 406 on the bottom superlattice 402, and a top superlattice 408 on the inter-superlattice sacrificial layer 406, as shown in FIG. 4A. The bottom superlattice 402 and the top superlattice 408 each include alternating channel layers 202 and sacrificial layers 410 stacked in the Z direction. The channel layers 202 may be formed of a first material. The sacrificial layers 410 may be formed of a second material. The etch selectivity of the second material (i.e., a ratio of the etch rate of the second material to the etch rate of the first material) is between about 10:1 to 500:1. Examples of the first material include pure silicon (Si), germanium (Ge), and silicon germanium (SiGe). Examples of the second material include silicon germanium (SiGe) having germanium (Ge) concentration of between about 10% and about 30%. The inter-superlattice sacrificial layer 406 may be formed of a material that has etch selectivity from the first material and the second material, for example, silicon germanium (SiGe) having a higher germanium (Ge) concentration of between about 35% and about 60%. The bottom superlattice 402 and the top superlattice 408 each may include between about 2 and about 10 pairs of the channel layer 202 and the sacrificial layer 410. The channel layers 202 each have a thickness of between about 5 nm and about 40 nm. The sacrificial layer 410 each have a thickness of between about 5 nm and about 40 nm. The inter-superlattice sacrificial layer 406 may have a thickness of between about 20 nm and about 100 nm.

The term “substrate” as used herein refers to a layer of material that serves as a basis for subsequent processing operations and includes a surface to be cleaned. The substrate 404 may be a silicon based material or any suitable insulating materials or conductive materials as needed. The substrate 404 may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The double superlattice deposition process in block 302 may include any appropriate deposition process, such as chemical vapor deposition (CVD), physical vapor deposition (PVD), epitaxial deposition process, or the like, performed in a processing chamber, such as the processing chamber 126, 128, or 130 shown in FIG. 1.

In block 304, a nanosheet patterning process is performed to form a nanosheet 412 and shallow trench isolations (STIs) 414, as shown in FIG. 4B. The nanosheet patterning process includes etching the top superlattice 408, the inter-superlattice sacrificial layer 406, and the bottom superlattice 402 into the substrate 404. The nanosheet 412 having a bottom nanosheet 416 etched from the bottom superlattice 402, and a top nanosheet 418 etched from the top superlattice 408, has a width in the X direction of between about 5 nm and about 60 nm and an aspect ratio of between about 1:10 and about 1:80. The etched portions of the substrate 404 are filled with dielectric material, such as silicon oxide (SiO₂), to a top surface of the remaining substrate 404, to form the shallow trench isolations (STIs) 414.

The nanosheet patterning process in block 304 may include any appropriate lithography and etch processes, such as photolithography, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

In block 306, a gate and spacer formation process is performed to form dummy gates 420 around the nanosheet 412, and spacers 208 on surfaces of the dummy gates 420 along the ZX plane, as shown in as shown in FIG. 4C. Gate cap layers 422 may be formed on the dummy gates 420 between the spacers 208. The dummy gates 420 may be formed of polysilicon. The spacers 208 may be formed of dielectric material, such as silicon oxycarbide (SiOₓC_{y}). The gate cap layer 422 may be formed of dielectric material, such as silicon nitride (Si₃N₄).

The gate and spacer formation process in block 306 may include any appropriate deposition process, such as chemical vapor deposition (CVD), physical vapor deposition (PVD), epitaxial deposition process, or the like performed in a processing chamber, such as the processing chamber 126, 128, or 130 shown in FIG. 1.

In block 308, a middle dielectric isolation (MDI) formation process is performed to selectively etch the inter-superlattice sacrificial layer 406 in the nanosheet 412 and fill the etched portions with dielectric material to form an MDI 210, as shown in FIG. 4D. The MDI 210 may be formed of dielectric material the same as or similar to the spacers 208.

The MDI formation process in block 308 may include any appropriate etch process, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

In block 310, an inner spacer formation process is performed to selectively etch the sacrificial layers 410 in the bottom nanosheet 416 and the top nanosheet 418, and fill the etched portions with dielectric material to form inner spacers 424, as shown in FIG. 4E. The inner spacers 424 may be formed of dielectric material the same as or similar to the spacers 208 having a composition of silicon (Si), oxygen (O), carbon (C), nitrogen (N), and boron (B).

The inner spacer formation process in block 310 may include any appropriate etch process, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

In block 312, a top cover spacer formation process is performed to deposit a top cover spacer 426 in a top portion of the semiconductor structure 400, as shown in FIG. 4F. The top cover spacer 426 may be deposited on exposed surfaces of the top nanosheet 418 and the spacer 208 around the top nanosheet 418 along the ZX plane, covering the exposed surface of the top nanosheet 418. The bottom nanosheet 416 and the spacer 208 around the bottom nanosheet 416 remain exposed along the ZX plane. The top cover spacer 426 may be formed of dielectric material the same as or similar to the spacers 208.

The top cover spacer formation process in block 312 may include any appropriate deposition process, such as chemical vapor deposition (CVD), physical vapor deposition (PVD), or the like, performed in a processing chamber, such as the processing chamber 126, 128, or 130 shown in FIG. 1.

In block 314, a bottom epitaxial (epi) source/drain (S/D) formation process is performed to form a bottom epi S/D 214, as shown in FIG. 4G. The bottom epi S/D 214 is epitaxially grown on the exposed surface of the bottom nanosheet 416 along the ZX plane. The bottom epi S/D 214 interfaces between the channel layers 202 in the bottom nanosheet 416 and a S/D contact to be formed in a bottom portion of the semiconductor structure 400, to minimize parasitic resistance. The bottom epi S/D 214 may be formed of silicon (Si) or silicon germanium (SiGe).

The bottom epi S/D 214 may be doped with p-type dopants such as boron (B) or gallium (Ga), with a concentration of between about 10²⁰ cm⁻³ and 5×10²¹ cm⁻³, depending upon the desired conductive characteristic of the bottom epi S/D 214. In some embodiments, the bottom epi S/D 214 is doped with n-type dopants, such as phosphorus (P), arsenic (As), or antimony (Sb), with a concentration of between about 10²⁰ cm⁻³ and 5×10²¹ cm⁻³, depending upon the desired conductive characteristic of the bottom epi S/D 214.

The bottom epi S/D formation process in block 314 may include an epitaxial deposition process, performed in a processing chamber, such as the processing chamber 128, or 130 shown in FIG. 1, in which the semiconductor structure 400 is exposed to a deposition gas. In some embodiments, the deposition gas includes a silicon-containing precursor, a germanium containing precursor, and a dopant source. The silicon-containing precursor may include silane (SiH₄), disilane (Si₂H₆), tetrasilane (Si₄H₁₀), or a combination thereof. The germanium-containing precursor may include germane (GeH₄), germanium tetrachloride (GeCl₄), and digermane (Ge₂H₆). The dopant source may include a precursor diborane (B₂H₆) or trimethylgallium Ga(CH₃)₃, including p-type dopants such as boron (B) or gallium (Ga). In the embodiments where the bottom epi S/D 214 is n-type doped, the dopant source includes a precursor phosphine (PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb).

The epitaxial deposition process may be performed at a temperature of between about 400° C. and about 800° C. Dopants in the bottom epi S/D 214 may be activated by a subsequent anneal process performed at a temperature of between 850° C. and about 1200° C.

In block 316, a bottom contact patterning and sacrificial fill process is performed to deposit a bottom inter-layer dielectric (ILD) 218 on uncovered surfaces of the spacers 208 around the bottom epi S/D 214 in the bottom portion of the semiconductor structure 400, and pattern the bottom ILD 218 to form a dummy contact 428, as shown in FIG. 4H. The bottom ILD 218 may be formed of dielectric material, such as silicon oxide (SiO₂). The dummy contact 428 may be formed of dielectric material, such as silicon oxide (SiO₂), silicon nitride (Si₃N₄), silicon carbide (SiC), or a combination thereof, that has etch selectivity from the bottom ILD 218 and withstands subsequent high temperature processes. Subsequent to the formation of the dummy contact 428, the top cover spacers 426 are removed to expose the surfaces of the top nanosheet 418 (shown in FIG. 4E) and the spacer 208 around the top nanosheet 418 along the ZX plane.

The bottom contact patterning and sacrificial fill process in block 316 may include any appropriate lithography and etch processes, such as photolithography, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

In block 318, a top epi S/D formation process is performed to form a top epi S/D 222, as shown in FIG. 4I. The top epi S/D 222 is epitaxially grown on the exposed surface of the top nanosheet 418 along the ZX plane. The top epi S/D 222 interfaces between the channel layers 202 in the top nanosheet 418 and a S/D contact to be formed in the top portion of the semiconductor structure 400, to minimize parasitic resistance. The top epi S/D 222 may be formed of silicon (Si) or silicon germanium (SiGe). Subsequent to the formation of the top epi S/D 222, a top ILD 226 is formed around the top epi S/D 222 on exposed surfaces of the spacers 208 and between the spacers 208. The top ILD 226 may be formed of dielectric material, such as silicon oxide (SiO₂).

The top epi S/D 222 may be doped with n-type dopants, such as phosphorus (P), arsenic (As), or antimony (Sb), with a concentration of between about 10²⁰ cm⁻³ and 5×10²¹ cm⁻³, depending upon the desired conductive characteristic of the top epi S/D 222. In the embodiments where the bottom epi S/D 214 is doped with p-type dopants, the top epi S/D 222 is doped with p-type dopants such as boron (B) or gallium (Ga), with a concentration of between about 10²⁰ cm⁻³ and 5×10²¹ cm⁻³, depending upon the desired conductive characteristic of the top epi S/D 222.

The top epi S/D formation process in block 318 may include an epitaxial deposition process, performed in a processing chamber, such as the processing chamber 128, or 130 shown in FIG. 1, in which the semiconductor structure 400 is exposed to a deposition gas. In some embodiments, the deposition gas includes a silicon-containing precursor, a germanium containing precursor, and a dopant source. The silicon-containing precursor may include silane (SiH₄), disilane (Si₂H₆), tetrasilane (Si₄H₁₀), or a combination thereof. The germanium-containing precursor may include germane (GeH₄), germanium tetrachloride (GeCl₄), and digermane (Ge₂H₆). The dopant source may include a precursor phosphine (PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb). In the embodiments where the top epi S/D 222 is p-type doped, the dopant source may include a precursor diborane (B₂H₆) or trimethylgallium Ga(CH₃)₃, including p-type dopants such as boron (B) or gallium (Ga).

The epitaxial deposition process may be performed at a temperature of between about 400° C. and about 800° C. Dopants in the top epi S/D 222 may be activated by a subsequent anneal process performed at a temperature of between 850° C. and about 1200° C.

In block 320, a replacement metal gate (RMG) process is performed to replace the dummy gates 420 with metal gates 204, as shown in FIGS. 4J and 4J′. FIG. 4J′ illustrates a cut out of the semiconductor structure 400 along the ZX plane including the line J′-J′ shown in FIG. 4J. The metal gates 204 may be formed of metal fill material, such as cobalt (Co) and tungsten (W). The metal gates 204 may be interfaced with the channel layers 202 and the MDI 210 via liners 206. The liners 206 may be formed of titanium nitride (TiN), tantalum nitride (TaN), titanium aluminum carbide (TiAlC), or tungsten (W).

The RMG process in block 320 may include any appropriate etch process, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

The metal fill process may be performed at a temperature of between about 150° C. and about 400° C. The metal fill process may be followed by various annealing steps, such as high-k annealing, reliability annealing, performed at a temperature of between about 700° C. and about 950° C.

In block 322, a top contact patterning and metal fill process is performed to pattern the top ILD 226 to form a top S/D contact 220, as shown in FIG. 4K. A top interface 224 that provides ohmic contact between the top epi S/D 222 and the top S/D contact 220.

The top S/D contact 220 may be formed of cobalt (Co) or tungsten (W) and may include a liner (not shown) formed of titanium nitride (TiN) or tungsten (W) therearound. The top interface 224 may be formed of metal silicide, such as titanium silicide (TiSi₂), molybdenum silicide (MoSi₂), cobalt silicide (CoSi₂), nickel (Ni₂Si), tantalum silicide (TaSi₂), or any combination thereof. An optional contact epi (not shown) may be formed between the top epi S/D 222 and the top interface 224 by a low temperature epitaxial deposition at a low temperature of between about 400° C. and about 900° C. The contact epi and top interface 224 may be formed in a cluster tool without vacuum break.

The top contact patterning and metal fill process in block 322 may include any appropriate lithography and etch processes, such as photolithography, performed in a processing chamber, such as the processing chamber 120 shown in FIG. 1, and any appropriate deposition process, such as chemical vapor deposition (CVD), physical vapor deposition (PVD), epitaxial deposition process, or the like, performed in a processing chamber, such as the processing chamber 126, 128, or 130 shown in FIG. 1. The low temperature epitaxial deposition process in block 322 may be performed in a processing chamber, such as the processing chamber 126, 128, or 130 shown in FIG. 1. The top contact patterning and metal fill process and the low temperature epitaxial deposition process in block 322 may be performed without breaking vacuum in a cluster tool such as the processing system 100.

In block 324, a via contact (VCT) and via contact to gate (VCG) patterning process is performed to form a bottom VCT 430, a top VCT 432, and a VCG 434, as shown in FIG. 4L. Dielectric layers 232 and 234 are deposited over the semiconductor structure 400. The bottom VCT 430 is formed by etching through the dielectric layers 232 and 234, the top ILD 226 and the bottom ILD 218 to the dummy contact 428. The top VCT 432 is formed by etching through the dielectric layers 232 and 234 to the top S/D contact 220. The VCG 434 is formed by etching through the dielectric layers 232 and 234 to the metal gate 204.

The dielectric layers 232 and 234 may be formed of silicon oxide (SiO₂), silicon nitride (Si₃N₄), or aluminum oxide (Al₂O₃). The dielectric layers 232 and 234 are formed of different materials.

The VCT and VCG patterning process in block 324 may include any appropriate lithography and etch processes, such as photolithography, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

In block 326, a dummy contact strip process is performed to selectively etch the dummy contact 428 and form an etched portion 436, as shown in FIG. 4M.

The dummy contact strip process in block 324 may include any appropriate etch process, such as photolithography, performed in a processing chamber, such as the processing chamber 120 shown in FIG. 1.

In block 328, a bottom replacement S/D contact formation process is performed to form a bottom S/D contact 212, as shown in FIG. 4N. The bottom S/D contact 212 is formed by filling the portion 436 etched in the dummy contact strip process in block 324 with a metal fill material, such as cobalt (Co) and tungsten (W). The bottom VCT 430 is filled with the metal fill material to a top surface of the top ILD 226 to form a contact plug 438. The bottom S/D contact 212 may be interfaced with the bottom epi S/D 214 via the bottom interface 216. The bottom S/D contact 212 may include a liner (not shown) formed of titanium nitride (TiN) or tungsten (W) therearound. The bottom interface 216 may be formed of metal silicide, such as titanium silicide (TiSi₂), molybdenum silicide (MoSi₂), cobalt silicide (CoSi₂), nickel (Ni₂Si), tantalum silicide (TaSi₂), or any combination thereof. An optional contact epi (not shown) may be formed between the bottom epi S/D 214 and the bottom interface 216 by a low temperature epitaxial deposition at a low temperature of between about 400° C. and about 900° C. The contact epi and the bottom interface 216 may be formed in a cluster tool without vacuum break.

The bottom replacement S/D contact formation process in block 328 may include any appropriate deposition process, such as chemical vapor deposition (CVD), physical vapor deposition (PVD), or the like performed in a processing chamber, such as the processing chamber 126, 128, or 130 shown in FIG. 1. The low temperature epitaxial deposition process in block 328 may be performed in a processing chamber, such as the processing chamber 126, 128, or 130 shown in FIG. 1. The bottom replacement S/D contact formation process and the low temperature epitaxial deposition process in block 328 may be performed without breaking vacuum in a cluster tool such as the processing system 100. The cluster tool may be the same as the cluster tool used to perform the top contact patterning and metal fill process and the low temperature epitaxial deposition process in block 322.

In block 330, a VCT and VCG fill process is performed to fill the bottom VCT 430, the top VCT 432, and the VCG 434 within the dielectric layers 232 and 234 with metal fill material, such as cobalt (Co) and tungsten (W) to form contact plugs 236, as shown in FIG. 4O.

The VCT and VCG fill process in block 330 may include any appropriate deposition process, such as chemical vapor deposition (CVD), physical vapor deposition (PVD), or the like performed in a processing chamber, such as the processing chamber 126, 128, or 130 shown in FIG. 1.

In block 332, a metal layer formation process is performed to form metal layers 228 on the dielectric layers 232 and 234 and embedded in a dielectric layer 230, as shown in FIG. 2A. The metal layers 228 may be formed of cobalt (Co) or tungsten (W). The dielectric layer 230 may be formed of silicon oxide (SiO₂), silicon nitride (Si₃N₄), or aluminum oxide (Al₂O₃).

The metal layer formation process in block 332 may include any appropriate lithography and etch processes, such as photolithography, performed in a processing chamber, such as the processing chamber 120 shown in FIG. 1, and any appropriate deposition process, such as chemical vapor deposition (CVD), physical vapor deposition (PVD), or the like performed in a processing chamber, such as the processing chamber 126, 128, or 130 shown in FIG. 1.

The embodiments described herein provide methods for complementary FET (CFET) devices. In the methods described herein, a dummy contact is deposited in place for a bottom source/drain (S/D) contact for a bottom FET module of a CFET before high temperature process, such epitaxial deposition processes and a replacement metal gate process, and subsequently replaced with a bottom S/D contact formed of metal. This replacement S/D contact allows the use of most optimized materials for a bottom S/D contact in the bottom FET module without any thermal budget constraints.

While the foregoing is directed to embodiments of the present disclosure, other and further embodiments of the disclosure may be devised without departing from the basic scope thereof, and the scope thereof is determined by the claims that follow.

1. A semiconductor structure forming a complementary field-effect transistor (CFET), comprising:
a metal gate;
a bottom field effect transistor (FET) module, the bottom FET module comprising:
a plurality of channel layers extending through the metal gate in a first direction; and
a bottom source/drain (S/D) contact electrically connected to the plurality of channel layers via a bottom epitaxial (epi) S/D and a bottom interface; and
a top FET module stacked on the bottom FET module in a second direction that is orthogonal to the first direction, the top FET module comprising:
a plurality of channel layers extending through the metal gate in the first direction; and
a top source/drain (S/D) contact electrically connected to the plurality of channel layers via a top epitaxial (epi) S/D and a top interface,
wherein the bottom S/D contact and the top S/D contact each comprise cobalt (Co) or tungsten (W).

2. The semiconductor structure of claim 1, wherein the metal gate comprises cobalt (Co) or tungsten (W).

3. The semiconductor structure of claim 1, wherein the plurality of channel layers in the top FET module and the plurality of channel layers in the bottom FET module each comprise silicon.

4. The semiconductor structure of claim 1, wherein the bottom epi S/D is p-type doped and the top epi S/D is n-type doped.

5. The semiconductor structure of claim 1, wherein the bottom epi S/D is n-type doped and the top epi S/D is p-type doped.

6. The semiconductor structure of claim 1, wherein the top interface and the bottom interface each comprise metal silicide.

7. A method of forming a complementary field-effect transistor (CFET), comprising:
performing a top cover spacer formation process to deposit a top cover spacer covering exposed surface of a top nanosheet and a spacer around the top nanosheet along a first plane orthogonal to a first direction, wherein:
the top nanosheet is stacked on a bottom nanosheet in a second direction orthogonal to the first direction, and
the top nanosheet and the bottom nanosheet each comprise a plurality of channel layers extending through a dummy gate in the first direction;
performing a bottom epitaxial (epi) source/drain (S/D) formation process to form a bottom epi S/D on an exposed surface of the bottom nanosheet along the first plane;
performing a bottom contact patterning and sacrificial fill process to deposit a bottom inter-layer dielectric (ILD) on surfaces of a spacer around the bottom epi S/D, pattern the bottom ILD, forming a dummy contact, and remove the top cover spacer;
performing a top epi S/D formation process to form a top epi S/D on an exposed surface of the top nanosheet along the first plane and a top ILD around the top epi S/D;
performing a replacement metal gate (RMG) process to replace the dummy gate with a metal gate;
performing a top contact patterning and metal fill process to pattern the top ILD, forming a top S/D contact;
subsequent to the bottom epi S/D formation process, the top epi S/D formation process, and the RMG process, performing a dummy contact strip process to selectively etch the dummy contact; and
performing a bottom replacement S/D contact formation process to form a bottom S/D contact in the portion etched in the dummy contact strip process.

8. The method of claim 7, wherein the bottom S/D contact, the top S/D contact, and the metal gate each comprise cobalt (Co) or tungsten (W).

9. The method of claim 7, wherein the dummy contact comprises silicon oxide (SiO₂), silicon nitride (Si₃N₄), silicon carbide (SiC), or a combination thereof.

10. The method of claim 7, wherein the bottom ILD and the top ILD each comprise silicon oxide (SiO₂).

11. The method of claim 7, wherein the bottom epi S/D is p-type doped and the top epi S/D is n-type doped.

12. The method of claim 11, further comprising:
performing an anneal process to activate dopants in the bottom epi S/D and the top epi S/D, prior to the dummy contact strip process.

13. The method of claim 7, wherein the bottom epi S/D formation process and the top epi S/D formation process are performed at a temperature of between 400° C. and 1200° C.

14. The method of claim 7, wherein the RMG process is performed at a temperature of between 150° C. and 950° C.

15. A semiconductor structure forming a complementary field-effect transistor (CFET), comprising:
a metal gate;
a bottom field effect transistor (FET) module, the bottom FET module comprising:
a plurality of channel layers extending through the metal gate in a first direction; and
a dummy contact connected to the plurality of channel layers via a bottom epitaxial (epi) S/D and a bottom interface; and
a top FET module stacked on the bottom FET module in a second direction that is orthogonal to the first direction, the top FET module comprising:
a plurality of channel layers extending through the metal gate in the first direction; and
a top source/drain (S/D) contact electrically connected to the plurality of channel layers via a top epitaxial (epi) S/D and a top interface,
wherein the dummy contact comprises the dummy contact comprises silicon oxide (SiO₂), silicon nitride (Si₃N₄), silicon carbide (SiC), or a combination thereof, and the top S/D contact comprises cobalt (Co) or tungsten (W).

16. The semiconductor structure of claim 15, wherein the metal gate comprises cobalt (Co) or tungsten (W).

17. The semiconductor structure of claim 15, wherein the plurality of channel layers in the top FET module and the plurality of channel layers in the bottom FET module each comprise silicon.

18. The semiconductor structure of claim 15, wherein the bottom epi S/D is p-type doped and the top epi S/D is n-type doped.

19. The semiconductor structure of claim 15, wherein the bottom epi S/D is n-type doped and the top epi S/D is p-type doped.

20. The semiconductor structure of claim 15, wherein the top interface and the bottom interface each comprise metal silicide.
